(19) United States
(12) Patent Application Publication
(10) Pub. No.: US 2008/0157303 A1
(43) Pub. Date: Jul. 3, 2008

(54) Structure of super thin chip scale package and method of the same

(75) Inventor: Wen-Kun Yang, Hsin-Chu City (TW)

Correspondence Address: BIRCH STEWART KOLASCH & BIRCH, PO BOX 747, FALLS CHURCH, VA, 22040-0747, US

(73) Assignee: Advanced Chip Engineering Technology Inc.

(21) Appl. No.: 11/646,306

(22) Filed: Dec. 28, 2006

(51) Int. Cl. H01L 23/495

(52) U.S. Cl. 257/676

(57) ABSTRACT

The present invention discloses a super thin chip scale package structure and method of the same. The super thin chip scale package structure comprises a substrate, a wafer with a plurality of die having a plurality of bonding pads, a first dielectric layer, a via conductive layer, a second dielectric layer, a redistribution layer trace and soldering bumps formed on the wafer in sequence. Due to minimizing the sizes of the package structure, the present invention can provides a super thin chip scale package structure. Especially, the method for manufacturing the super thin chip scale package comprises sawing the wafer and back-lapping the back side of the wafer and etching the back side of the substrate to provide the super thin chip scale package structure. Accordingly, the present invention can minimize the size of the package structure, and improve the manufacturing process effectively.

### BACKGROUND OF THE INVENTION

1. Field of the Invention

This invention relates to a chip scale package, and more particularly to a super thin chip scale package and method of the same, which the super thin package structure can minimize the package size and improve the process effectively.

2. Description of the Prior Art

In recent years, the high-technology electronics manufacturing industries launch more feature-packed and humanized electronic products. These new products that hit the showroom are lighter, thinner, and smaller in design. In the manufacturing of these electronic products, the key component has to be the integrated circuit (IC) chip inside any electronic product.

Rapid development of semiconductor technology has led to rapid progress of a reduction in size of semiconductor packages, the adoption of multi-pin, the adoption of fine pitch, the minimization of electronic components and the like. The purposes and the advantages of wafer level package includes decreasing the production cost, decreasing the effect caused by the parasitic capacitance and parasitic inductance by using the shorter conductive line path, acquiring better SNR (i.e. signal to noise ratio). Furthermore, the size of a wafer-level package product is close to the size of a chip, and therefore, the size of the chip determines the package volume.

The chip-scale package (CSP) has been conventionally formed by a method in which a semiconductor wafer is cut into semiconductor chips, then the semiconductor chips are mounted on a base substrate serving as a package base at predetermined positions and bonded thereto, and they are collectively sealed with a resin, thereafter the sealing resin and the base substrate are cut into pieces together at the parts between the semiconductor chips. In another conventional method, a semiconductor wafer (not being cut into semiconductor chips yet) is mounted on a base substrate and bonded thereto, then the semiconductor wafer and the base substrate are cut simultaneously, and the cut and divided semiconductor chips and package bases are sealed with a resin.

Further, the operability, performance, and life of an IC chip are greatly affected by its circuit design, wafer manufacturing, and chip packaging. For this present invention, the focus will be on chip packaging technique. Since the features and speed of IC chips are increasing rapidly, the need for increasing the conductivity of the circuitry is necessary so that the signal delay and attenuation of the dies to the external circuitry are reduced. A chip package that allows good thermal dissipation and protection of the IC chips with a small overall dimension of the package is also necessary for higher performance chips. These are the goals to be achieved in chip packaging.

There are a vast variety of existing chip package techniques such as ball grid array (BGA), wire bonding, flip chip for mounting a die on a substrate via the bonding points on both the die and the substrate. The inner traces help to fan out the bonding points on the bottom of the substrate. The solder balls are separately planted on the bonding points for acting as an interface for the die to electrically connect to the external circuitry. Similarly, pin grid array (PGA) is very much like BGA, which replaces the balls with pins on the substrate and PGA also acts an interface for the die to electrically connect to the external circuitry.

Both BGA and PGA packages require wiring or flip chip for mounting the die on the substrate. The inner traces in the substrate fan out the bonding points on the substrate, and electrical connection to the external circuitry is carried out by the solder balls or pins on the bonding points. As a result, this method fails to reduce the distance of the signal transmission path but in fact increase the signal path distance. This will increase signal delay and attenuation and decrease the performance of the chip.

However, in the manufacturing method, wafer level chip scale package (WLCSP) has an advantage of being able to print the redistribution circuit directly on the die by using the peripheral area of the die as the bonding points. It is achieved by redistributing an area array on the surface of the die, which can fully utilize the entire area of the die. The bonding points are located on the redistribution circuit by forming flip chip bumps so the bottom side of the die connects directly to the printed circuit board (PCB) with micro-spaced bonding points.

Although WLCSP can greatly reduce the signal path distance, it is still very difficult to accommodate all the bonding points on the die surface as the integration of die and internal components gets higher. The pin count on the die increases as integration gets higher so the redistribution of pins in an area array is difficult to achieve. Even if the redistribution of pins is successful, the distance between pins will be too small to meet the pitch of a printed circuit board (PCB). That is to say, such process and structure of prior art will suffer yield and reliability issues owing to the huge size of package. The further disadvantage of former method are higher costs and time-consuming for manufacture.

In view of the aforementioned, the present invention provides a new structure and method for a super thin chip scale package that minimizes the thickness of package structure for a wafer level package to overcome the above drawback.

### SUMMARY OF THE INVENTION

The present invention will descript some preferred embodiments. However, it is appreciated that the present invention can extensively perform in other embodiments except for these detailed descriptions. The scope of the present invention is not limited to these embodiments and should be accorded the following claims.

One objective of the present invention is to provide a structure for chip scale package, which can allow minimizing the size of chip scale package.

Another objective of the present invention is to provide a method for chip scale package, which can improve the manufacturing process of chip scale package effectively.

The present invention provides a structure of super thin chip scale package, comprising a substrate, a plurality of dice having a plurality of bonding pads formed thereon, a first dielectric layer formed on the plurality of dice to expose the partial surface of bonding pads, a via conductive layer filled within the space among the first dielectric layer; a redistribution layer trace formed on the via conductive layer and the first dielectric layer, a second dielectric layer formed on the first dielectric layer and the redistribution layer trace to expose a partial surface of the redistribution layer trace, a plurality of soldering bumps formed on the space among the second dielectric layer, and a cover protection layer formed below the substrate, wherein the plurality of soldering bumps can be electrically connected with the bonding pads through the via conductive layer and the redistribution layer trace.

The present invention provides a method for manufacturing a super thin chip scale package, comprising preparing a wafer with a plurality of dice having a plurality of bonding pads formed thereon, sawing the wafer attached on a dicing tape to form a plurality of slots till a first predetermined depth, attaching the wafer below a lapping tape flame and back-lapping the wafer till a second predetermined depth, bonding the wafer attached to a substrate having a die attached film, removing the lapping tape flame, vacuum filling core pastes into the space among the plurality of dice and the die attached film, forming a first dielectric layer on the wafer and expose the partial surfaces of the plurality of dice, sputtering a via conductive layer (seed metal layers) to fill the space among the plurality of first dielectric layer, coating a redistribution layer trace on the via conductive layer and the first dielectric layer to expose the partial surfaces of the plurality of first dielectric layer, coating a plurality of second dielectric layer to fill the space among the via conductive layer and exposing the partial surfaces of the via conductive layer, etching the back side of the substrate to remove the partial region of the substrate, forming a cover protection layer on the back side of substrate, and welding a plurality of soldering bumps on the space among the plurality of second dielectric layer.

### BRIEF DESCRIPTION OF THE DRAWINGS

The foregoing aspects and many of the attendant advantages of this invention will become more readily appreciated as the same becomes better understood by reference to the following detailed description, taken in conjunction with the accompanying drawings, wherein:

FIG. 1 illustrates is a schematic diagram of an individual separated structure of a super thin chip scale package according to the present invention;

FIG. 2a to 2g illustrate cross-section diagrams of forming a wafer to a panel according to the present invention;

FIG. 3a illustrates cross-section diagram of the back-site of the substrate after etching according to the present invention;

FIG. 3b illustrates cross-section diagram of forming a cover protection layer on the back-site of the substrate according to the present invention;

FIG. 4a to 4d illustrate cross-section diagrams of forming the first dielectric layer, the via conductive layer, the redistribution layer trace, the second dielectric layer and the soldering bumps on a panel of FIG. 3b according to the present invention;

FIG. 5 illustrates a cross-section diagram of sawing a super thin chip scale package according to the present invention; and

FIG. 6 illustrates a flow chart of a method of manufacturing a super thin chip scale package according to the present invention.

### DESCRIPTION OF THE PREFERRED EMBODIMENT

In the following description, numerous specific details are provided in order to give a through understanding of embodiments of the invention. Referring now to the following description wherein the description is for the purpose of illustrating the preferred embodiments of the present invention only, and not for the purpose of limiting the same. One skilled in the relevant art will recognize, however, that the invention may be practiced without one or more of the specific details, or with other methods, components, materials, etc.

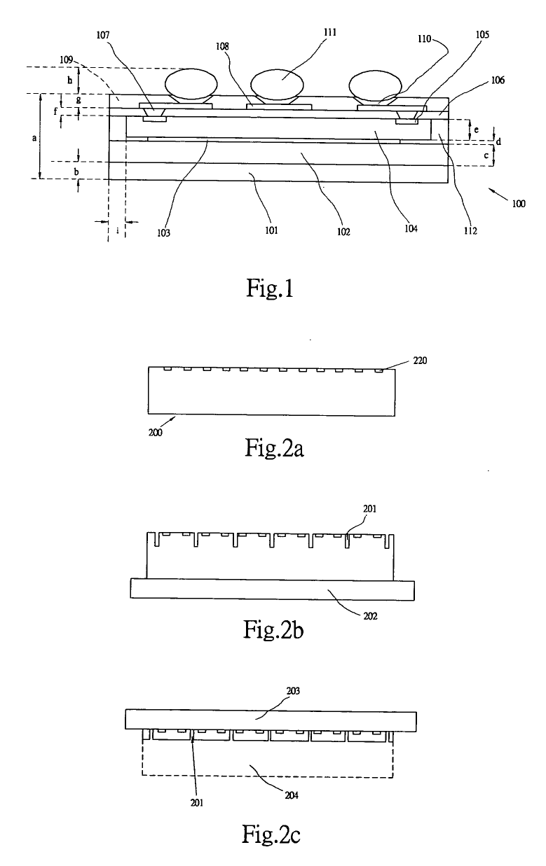

Referring to FIG. 1, it is a schematic diagram of an individual separated structure of a super thin chip scale package 100 according to the present invention. The structure of the super thin chip scale package 100 is an individual separated structure of the chip scale package after sawing. The super thin chip scale package 100 includes a cover protection layer 101, a substrate 102, a die attached film 103, a die 104, a plurality of bonding pads 105, a first dielectric layer 106, a via conductive layer 107, a redistribution layer trace 108, a seconding dielectric layer 109, an under bump metal 110, a plurality of soldering bumps 111 and core pastes 112.

The die 104 having a plurality of bonding pads 105 are formed on the substrate 102, and the bonding pads 105 are formed within the die 104 and on the top side of the die 104, so that the surface of bonding pads 105 can be exposed. The die attached film 103 is formed between the die 104 and the substrate 102, and placed below each die 104. The core pastes 112 are filled into the space surrounding the die 104 and the die attached film 103. The cover protection layer 101 is formed at the lower surface of the substrate 102.

Further, the first dielectric layer 106 is formed on the die 104 having a plurality of bonding pads 105 and the core pastes 112, and the partial surface of the die 104 are exposed by subsequent exposure/development or lithography. Next, the via conductive layer 107 (by sputtering seed metal Ti/Cu) is formed on the exposed surface of the bonding pads 105 of the die 104 to couple to the die 104 and to construct the redistribution layer trace 108. The redistribution layer trace 108 is partially formed on the via conductive layer 107 (by using PR to form the pattern of RDL and electroplating Cu/Au or Cu/Ni/Au then PR strip and wet metal etching to form the RDL 108) and the first dielectric layer 106 to cover the via conductive metal layer 107. The second dielectric layer 109 is formed on the first dielectric layer 106 and the redistribution layer trace 108, and the partial surfaces of the redistribution layer trace 108 are exposed to electrically connect to the plurality of soldering bumps 111.

In one embodiment, the structure further comprises the under bump metal 110 formed between the redistribution layer trace 108 and the soldering bumps 111 to avoid the inter-diffusion between the redistribution layer trace 108 and the soldering bumps 111.

In one embodiment, the thickness b of the cover protection layer 101 is approximately 30-50 μm. The thickness c of the substrate 102 is approximately 50-60 μm. The thickness d of the die attached film 103 is approximately 10 μm, and the thickness e of the die 104 is approximately 50 μm. The thickness f of first dielectric layer 106 is approximately 5 μm, and the thickness g of the second dielectric layer 109 is approximately 20 μm. The thickness h of the soldering bumps 111 is approximately 80-200 μm. The width i of the core pastes 112 is approximately 20 μm, and the width i means the distance form the edge of the die 104 to the divided edge of individual separated structure. Thus, the total thickness a of the chip scale package 100 is approximately less than 200 μm without the thickness of the soldering bumps 111. Accordingly, the present invention can provide a super thin chip scale package structure.

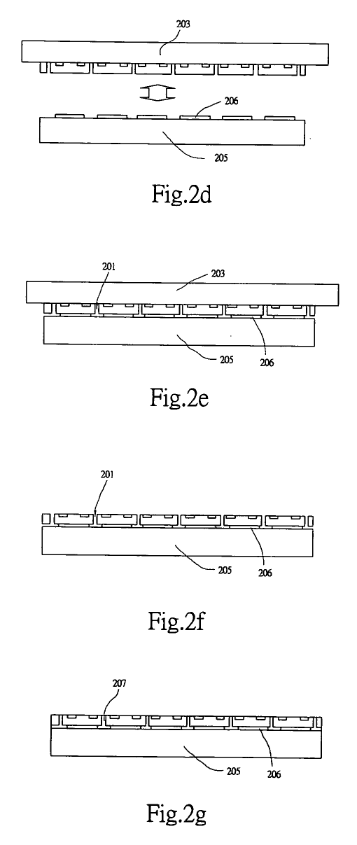

The present invention further provides a method for manufacturing a structure of the super thin chip scale package 100. FIG. 2a to 5 are cross-section diagrams showing the process for forming the super thin chip scale package 100.

FIG. 2a to 2g illustrate cross-section diagrams of forming a wafer to a panel according to the present invention. The wafer 200 has a plurality of dice with the plurality of bonding pads 220 formed thereon. Refer to FIG. 2a, the wafer 200 is coating with a dielectric layer which its thickness is approximately 2-3 μm, and the dice on the wafer 200 have the plurality of bonding pads 220. The wafer 200 is mounted on a dicing tape 202 and a step of sawing is performed on the wafer 200 till a first predetermined depth by a dicing blade with a specific thickness, thereby forming pluralities of slots 201 between dice, as shown in FIG. 2b. The wafer 200 has a plurality of slots 201 formed on the die 200 after sawing, and the width of slots 201 is substantially equivalent the dicing blade with a specific thickness. Then, the dicing tape 202 is removed form the back side of the wafer 200.

After sawing the wafer 200 till a first predetermined depth, a first lapping tape flame 203 is attached on the surface having dice of the wafer 200. The wafer 200 is back-lapped form the back side of the wafer 200 till a second predetermined depth, and the back lapping area 204 is removed, as shown in the dotted area of FIG. 2c. The aforementioned process is named Dicing before Lapping (DBL).

In one embodiment, the first predetermined depth is approximately 75 μm, and the second predetermined depth is approximately 50 μm. It is noted that the second predetermined depth is substantially less than or equivalent the depth of the first predetermined depth to ensure that the wafer 200 is divided into a plurality of individual die (note: the depth is count from the active surface of wafer (die)). The first and second predetermined depth also can be modified according to the requirements of different conductions.

In one embodiment, the material of substrate 205 includes rigid based materials, and the rigid based materials may be metal, alloy 42, Kovar, organic, glass, ceramic or silicon. Further, the alloy metal is preferably composed by alloy 42 that is a nickel iron alloy whose coefficient of expansion makes it suitable for joining to silicon chips in miniature electronic circuits and consists of nickel 42@ and ferrous (iron) 58@. The alloy metal also can be composed by Kovar which consists of nickel 29@ cobalt 17@ and ferrous (iron) 54@.

In one embodiment, the material of the cover protection layer 209 includes epoxy and rubber. In one embodiment, the material of the first dielectric layer 210 and second dielectric layer 213 includes benzocyclobutene (BCB), Siloxane polymer (SINR) or polyimide (PI). It is noted that the materials of the present invention are only used to illustrate rather than limit the present invention.

Refer to FIG. 2d, the back-site of the structure of FIG. 2c is bonded with a substrate 205 having a plurality of die attached film 206 to form the combination structure as shown in FIG. 2e. Refer to FIG. 2f, pre-curing the die 200 attached on the die attached film 206 and the substrate 205, and then the first lapping tape flame 203 is peeled off from the wafer 200. Herein, the peeling off treatment is also called “de-tapping”. After de-tapping of the first lapping tape flame 203, the core pastes 112 are printed to refill into the space among the dice of the wafer 200 and the space among die attached film 206, as shown in FIG. 2g.

Then, the wafer 200 attached on the substrate 205 is treated in vacuum condition and the core pastes 112 are soft-baked. Optionally, the wafer 200 attached on the substrate 205 is spinning to firm the uniformity of the structure. The partial regions of the core pastes 112 are removed to open the die area by the photo mask due to their photosensitive property. The wafer 200 is etched by plasma etching method, and then cleaning the wafer 200 to remove the residual material by the quick dump rinse (QDR) method.

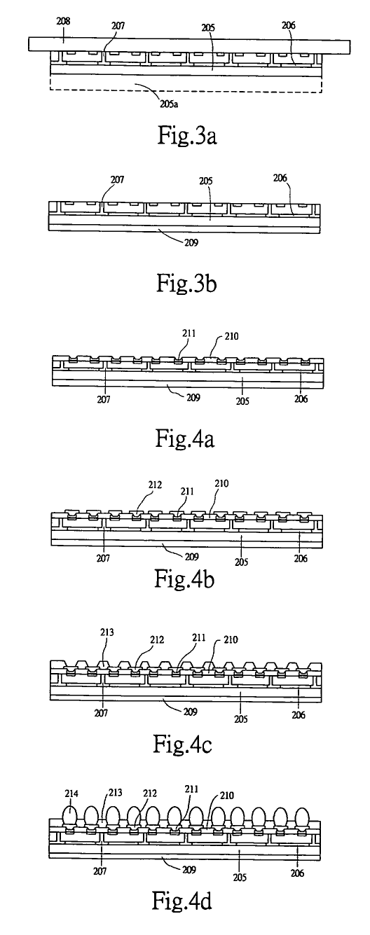

Refer to FIG. 3a, the structure of FIG. 2g is taping below a second lapping tape flame 208 with the wafer 200, and the partial back regions of the substrate 205, the etching area 205a, are removed by etching, as shown in the dotted area of FIG. 3a. Then, the back side of the wafer 200 is cleaned by the quick dump rinse (QDR) method, and the second lapping tape flame 208 is de-taping from the wafer 200. In FIG. 3b, a cover protection layer 209 is printing on the back side of the wafer 200, and then the cover protection layer 209 is cured.

In one embodiment, the step of removing the etching area 205a is performed by a wet etching method.

Refer to FIG. 4a to 4d, they illustrate schematic diagrams of forming the first dielectric layer 210, the via conductive layer 211, the redistribution layer trace 212, the second dielectric layer 213 and the soldering bumps 214 on a panel of FIG. 3b according to the present invention. In FIG. 4a, a first dielectric layer 210 is patterned on the wafer 200, and the plurality of bonding pads 220 attached on the wafer 200 is exposed. Then, a seed metal layer (a via conductive layer 211) is sputtering on the first dielectric layer 210 and the plurality of bonding pads 220 attached on the wafer 200, and the material of seed metal layer includes Ti/Cu. Next, coating the photo resist layer (not shown) on the seed metal layer, soft-baking the photo resist layer and photo masking the photo resist layer. The photo resist layer is developed to open the pattern of redistribution layer (RDL), and cleaned by plasma. A redistribution layer trace 212 is plating on the space among the first dielectric layer 210 by electroplating, and the material of redistribution layer trace 212 includes Cu/Au or Cu/Ni/Au. After striping the photo resist layer, the seed metal layer is removed by wet etching to form the redistribution layer (RDL) trace 212 on the via conductive layer 211 and the first dielectric layer 210, and the partial surfaces of the first dielectric layer 210 are exposed, as shown in FIG. 4b.

Refer to FIG. 4c, a second dielectric layer 213 is coated on the first dielectric layer 210 and the redistribution layer (RDL) trace 212, and photo masking the second dielectric layer 213 to open the solder ball metal pads. The open area of second dielectric layer 213 is cleaned by plasma, and then the second dielectric layer 213 is cured.

Subsequently, a seed metal layer (not shown) is sputtered on the second dielectric layer 213 and the exposed (solder ball metal pads) surface of the redistribution layer (RDL) trace 212 is open for under bump metal (UBM). The second photo resist layer is coating on the seed metal layer, and the second photo resist layer is soft-baking and photo masking for UBM. The second photo resist layer is developing to open the solder ball metal pads, and then is cleaned by plasma method. A Cu/Ni/Au film is plating by electroplating. Next, the second photo resist layer is striped, and wet etching the seed metal layer to form the UBM, and cleaned by a QDR method. Optionally, the solder pastes are printing on the UBM pads by an IR reflow method to form bump. A plurality of soldering bumps 214 are bonding on the under bump metal (UBM) to fill the space among the second dielectric layer 213, as shown in FIG. 4d.

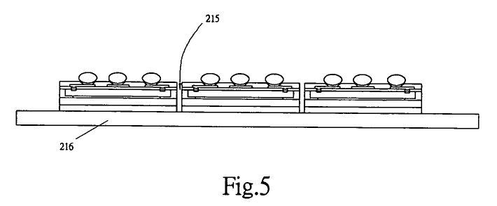

Refer to FIG. 5, it illustrates a cross section diagram of sawing a super thin chip scale package to perform the final testing and singulation process according to the present invention. Next, the panel wafer level final testing is performing, and the wafer map with the testing result is generated. The structure of FIG. 4d is mounting on a second dicing tape 216, and sawing the structure of FIG. 4d to separate to form individual chip scale package (CSP) from the sawed positions, such as the position pointed by the arrow 215. The chip scale package (CSP) is picking and placing onto the tray for FGS shipping.

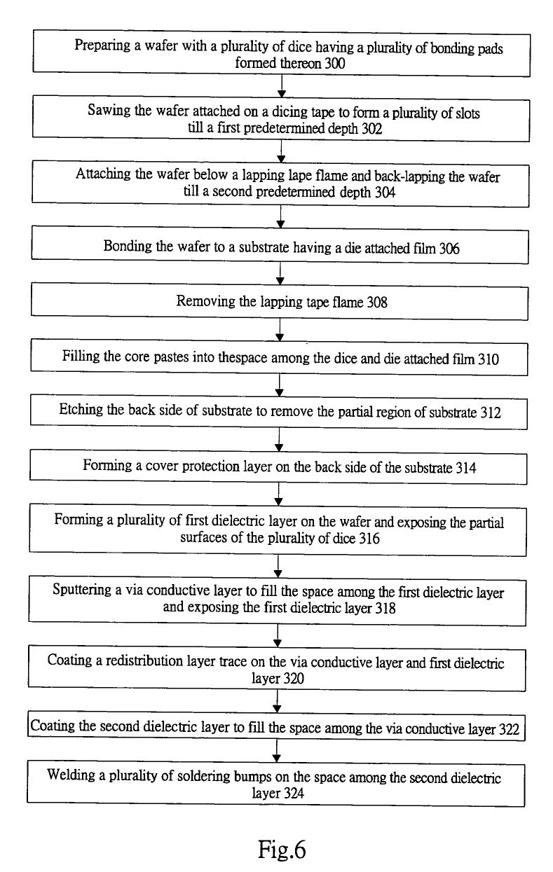

According to the aspect of the present invention, the present invention further provides a method for manufacturing a super thin chip scale package 100. FIG. 6 illustrates a flow chart of a method of manufacturing a super thin chip scale package 100 according to the present invention. The steps are illustrated as follows. First, preparing a wafer 200 with a plurality of dice having a plurality of bonding pads 220 formed thereon in step 300. Sawing the wafer 200 attached on a dicing tape 202 to form a plurality of slots 201 till a first predetermined depth in step 302. Then, the wafer 200 is attached below a lapping tape flame 203, and the back side of the wafer 200 is back-lapping till a second predetermined depth in step 304. The wafer 200 attached below the lapping tape flame 203 is bonding with a substrate 205 having a plurality of die attached film 206 in step 306. The lapping tape flame 203 is removed to expose the surface of wafer 200 in step 308. The core pastes 207 are filled into the space among the wafer 200 with the plurality of dice and the plurality of die attached film 206 patterned on the substrate 205 in step 310. Next, the back side of substrate 205 is etched to remove the partial region of the substrate 205 in step 312. A cover protection layer 209 is formed on the back side of substrate 205 in step 314. The step 312 and 314 can be modified process after the step 322 and before the step 324.

Subsequently, a first dielectric layer 210 is patterned on the wafer 200 and the partial surfaces of the wafer 200 are exposed in step 316. A via conductive layer 211 is sputtering to fill the space among the plurality of first dielectric layer 210 in step 318. Then, a redistribution layer trace 212 is coating on the seed metal layer and the first dielectric layer 210 to expose the partial surfaces of the plurality of first dielectric layer 210 in step 320. A plurality of second dielectric layer 213 is coating to fill the space among the via conductive layer 211 in step 322. A plurality of soldering bumps 214 are welding on the space among the plurality of second dielectric layer 213 in step 324.

It is noted that the material and thickness of the material are illustrated to describe but not to limit the present invention. The material and thickness of the material can be modified according to the requirements of different conductions. Herein, according to the present invention, the present invention allows reducing the sizes and shortening the manufacturing time. Further, the present invention can minimize the size of chip scale package structure, and improve the manufacturing processes effectively. Therefore, the super thin chip scale package structure and method of the same disclosed by the present invention can provide unexpected effect than prior art, and solve the problems of prior art. The method may apply to wafer or panel industry and also can be applied and modified to other related applications.

As will be understood by a person skilled in the art, the foregoing preferred embodiments of the present invention are illustrative of the present invention, rather than limiting the present invention. Having described the invention in connection with a preferred embodiment, modification will suggest itself to those skilled in the art. Thus, the invention is not to be limited by this embodiment. Rather, the invention is intended to cover various modifications and similar arrangements included within the spirit and scope of the appended claims, the scope of which should be accorded the broadest interpretation so as to encompass all such modifications and similar structures.

What is claimed is:

1. A structure of super thin chip scale package, comprising:
a substrate;
a plurality of dice having a plurality of bonding pads formed thereon;
a first dielectric layer formed on said plurality of dice to expose the partial surface of said bonding pads;
a via conductive layer filled within the space among said first dielectric layer;
a redistribution layer trace formed on said via conductive layer and said first dielectric layer;
a second dielectric layer formed on said first dielectric layer and said redistribution layer trace to expose partial surfaces of said redistribution layer trace;
a plurality of soldering bumps formed on the space among said second dielectric layer; and
a cover protection layer formed below said substrate;
wherein said plurality of soldering bumps can be electrically connected with said bonding pads through said via conductive layer and said plurality of redistribution layer trace.

2. The structure in claim 1, further comprising a die attached film patterned between said substrate and said plurality of dice.

3. The structure in claim 1, further comprising core pastes filled the space among said plurality of dice.

4. The structure in claim 3, wherein the material of said core pastes includes silicon rubber, silicone resin or epoxy resin.

5. The structure in claim 1, wherein the material of said substrate includes rigid based materials.

6. The structure in claim 5, wherein said rigid based materials includes metal, alloy, organic, glass, ceramic or silicon.

7. The structure in claim 6, wherein said alloy includes alloy42 (nickel 42@ and ferrous (iron) 58@), Kovar (nickel 29@, cobalt 17@ and ferrous (iron) 54@).

8. The structure in claim 1, wherein material of said first dielectric layer and second dielectric layer includes benzocyclobutene (BCB), Siloxane polymer (SINR) or polyimide (PI).

9. The structure in claim 1, wherein material of said cover protection layer include epoxy and rubber.

10. The structure in claim 1, wherein thickness of said substrate is approximately 50-60 μm.

11. The structure in claim 1, wherein thickness of said die is approximately 50 μm.

12. The structure in claim 1, wherein thickness of said substrate is approximately 50-60 μm.

13. The structure in claim 1, wherein thickness of said first dielectric layer is approximately 5 μm.

14. The structure in claim 1, wherein thickness of said second dielectric layer is approximately 20 μm.

15. The structure in claim 1, wherein thickness of said cover protection layer is approximately 30-50 μm.

16. The structure in claim 1, wherein thickness of said super thin chip scale package structure is approximately 200 μm.

17. A method for manufacturing a super thin chip scale package, comprising:
preparing a wafer with a plurality of dice having a plurality of bonding pads formed thereon;
sawing said wafer attached on a dicing tape to form a plurality of slots till a first predetermined depth;
attaching said wafer below a lapping tape flame and back-lapping said wafer till a second predetermined depth;
bonding said sawed wafer to a substrate having a die attached film;
removing said lapping tape flame;
filling core pastes into the space among said plurality of dice and said die attached film;
etching the back side of said substrate to remove the partial region of said substrate;
forming a cover protection layer on the back side of said substrate;
forming a plurality of first dielectric layer on said wafer and expose the partial surfaces of said plurality of dice;
sputtering a via conductive layer to fill the space among said plurality of first dielectric layer;
forming a redistribution layer trace on said via conductive layer and said first dielectric layer to expose the partial surfaces of said plurality of first dielectric layer;
coating a plurality of second dielectric layer to fill the space among said via conductive layer and exposing the partial surfaces of said via conductive layer; and
welding a plurality of soldering bumps on the space among said plurality of second dielectric layer.

18. The method in claim 17, further comprising a step of forming a UBM structure before printing a solder paste or solder ball placement on the UBM.

19. The method in claim 17, further comprising a step of mounting said super thin chip scale package structure on said dicing tape to separate into individual chip.

20. The method in claim 17, wherein said step of etching the back side of said substrate is by wet etching method.

21. The method in claim 17, wherein said first predetermined depth is approximately 75 μm.

22. The method in claim 17, wherein said second predetermined depth is approximately 50 μm.

23. The method in claim 17, wherein the thickness of said super thin chip scale package is approximately less than 200 μm.
